(19) United States
(12) Patent Application Publication
(10) Pub. No.: US 2015/0201756 A1
(43) Pub. Date: Jul. 23, 2015

(54) THIN-TYPED DISPLAY CAPABLE OF DISPOSING ON A WALL

(71) Applicant: BENQ Corporation, Taipei (TW)

(72) Inventor: Wei-Chieh Chen, Taoyuan City (TW)

(21) Appl. No.: 14/598,245

(22) Filed: Jan. 16, 2015

(30) Foreign Application Priority Data
Jan. 17, 2014 (TW) 103101717

(51) Int. Cl. A47B 97/00; H05K 5/02; H05K 5/00

(52) U.S. Cl. CPC A47B 97/001; H05K 5/0017; H05K 5/0217

(57) ABSTRACT

A thin-typed display which can be disposed on a wall includes a casing and a holder. A displaying panel is disposed on the casing, and the casing further includes a sunken structure. The holder is detachably disposed on the casing. The holder includes a base, a positioning portion and an engaging portion. The base includes a first edge and a second edge opposite to each other. The positioning portion is bent from the first edge and disposed on the wall. The engaging portion is bent from the second edge. The engaging portion inserts into the sunken structure to assemble the holder with the casing.

### BACKGROUND OF THE INVENTION

1. Field of the Invention

The present invention relates to a thin-typed display, and more particularly, to a thin-typed display with preferred aesthetic appearance and can be conveniently installed on the wall by a detachable holder.

2. Description of the Prior Art

With the advanced technology, the display trends towards thin-typed design for preferred aesthetic. The conventional thin-typed display is difficult to be assembled with a wall hanging component due to the thin structure of the display. The conventional thin-typed display may include the base connected to a bottom of the thin-typed display, to make the thin-typed display stand upon a tabletop. The conventional thin-typed display further can form a plurality of screwing holes on a rear housing of the thin-typed display, and an external holder is directly locked on the outer surface of the rear housing via the screwing holes to hang the thin-typed display on the wall. However, the rear housing of the conventional thin-typed display must be increased to accommodate a screw locking mechanism for matching with the wall hanging component, so the conventional wall hanging display has inaesthetic appearance and operating process of the external holder is complicated due to its huge volume.

### SUMMARY OF THE INVENTION

The present invention provides a thin-typed display with preferred aesthetic appearance and can be conveniently installed on the wall by a detachable holder for solving above drawbacks.

According to the claimed invention, a thin-typed display capable of being disposed on a wall includes a casing and a holder. A displaying panel is disposed on the casing, and the casing includes a sunken structure. The holder is detachably disposed on the casing. The holder includes a base, a positioning portion and an engaging portion. The base has a first edge and a second edge opposite to each other. The positioning portion is bent from the first edge and disposed on the wall. The engaging portion is bent from the second edge and inserts into the sunken structure to assemble the holder with the casing

The present invention disposes the sunken structure into an interval between components inside the casing instead of increasing thickness of the casing, the holder is detachably assembled with the sunken structure, and the casing can stand upon the table or be hanged on the wall stably by the holder. Comparing to the prior art, the holder is tightly attached to the lower side of the casing, and the thin-typed display of the present invention has advantages of preferred aesthetic appearance and convenient operating process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 respectively are diagrams of a thin-typed display in different views according to an embodiment of the present invention.

FIG. 3 and FIG. 4 respectively are diagrams of a holder in different views according to the embodiment of the present invention.

FIG. 5 is a sectional view of assembly of a casing and the holder according to a first embodiment of the present invention.

FIG. 6 is a diagram of the holder according to a second embodiment of the present invention.

FIG. 7 is a sectional view of assembly of the casing and the holder according to the second embodiment of the present invention.

FIG. 8 is a diagram of the thin-typed display according to another embodiment of the present invention.

### DETAILED DESCRIPTION

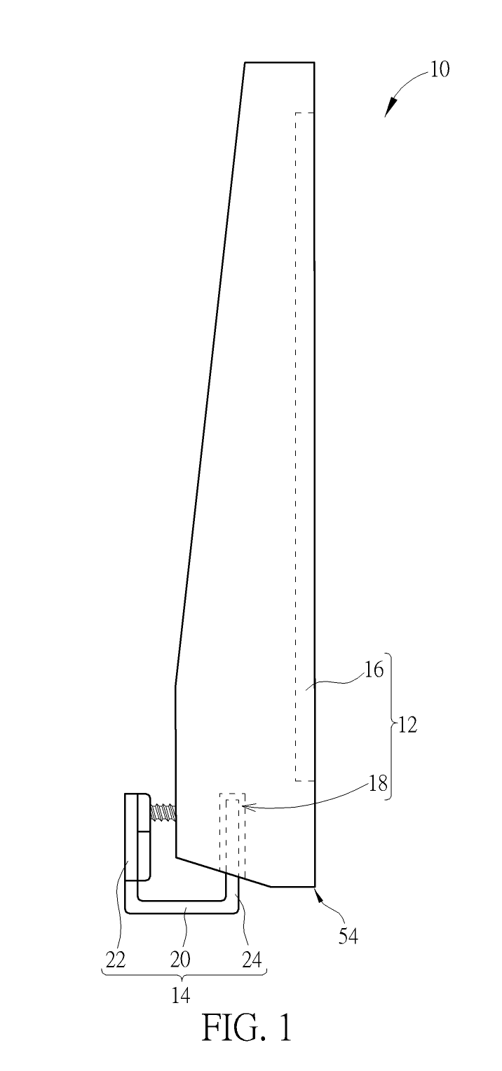

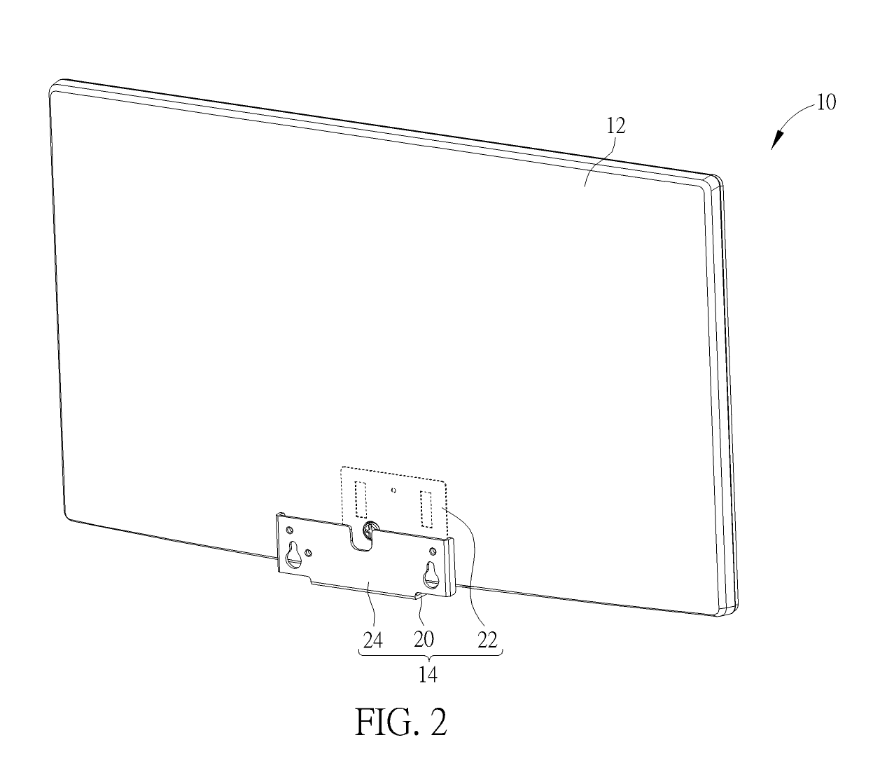

Please refer to FIG. 1 and FIG. 2. FIG. 1 and FIG. 2 respectively are diagrams of a thin-typed display 10 in different views according to an embodiment of the present invention. The thin-typed display 10 includes a casing 12 and a holder 14. The casing 12 can stand upon a table or be hanged on a wall by the holder 14 according to application of the thin-typed display 10. The casing 12 includes a displaying panel 16 and a sunken structure 18. The displaying panel 16 is disposed on a front (the display surface) of the casing 12, and the sunken structure 18 is disposed on a bottom of the casing 12. The holder 14 is detachably assembled with the casing 12 via the sunken structure 18, and the thin-typed display 10 can be put on the table or hanged on the wall by fixing function of the holder 14.

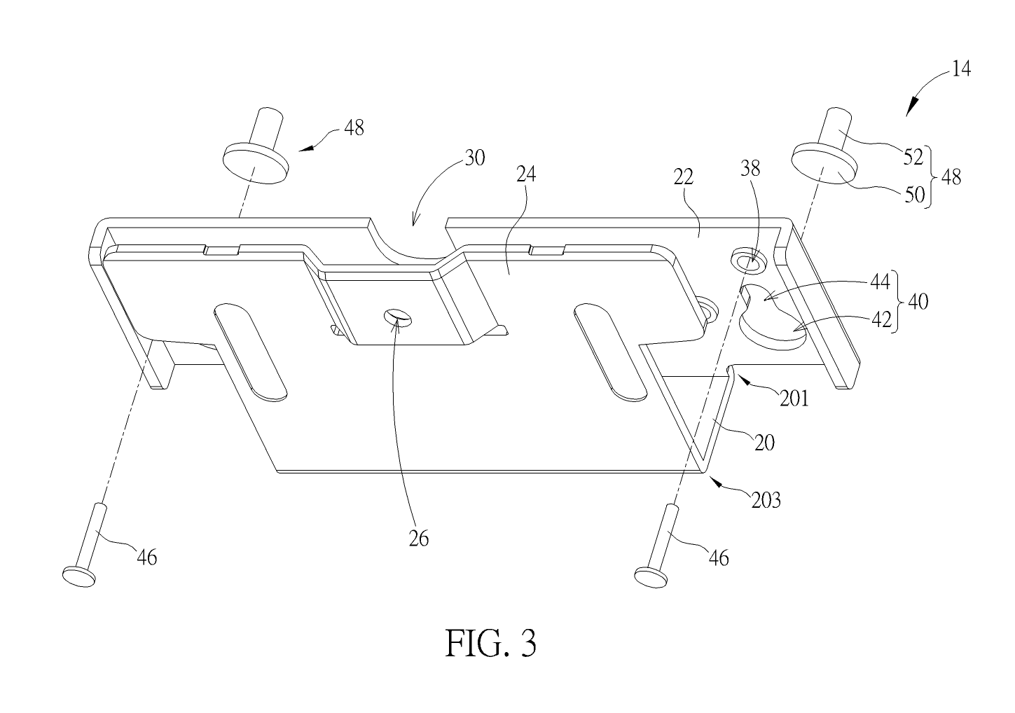

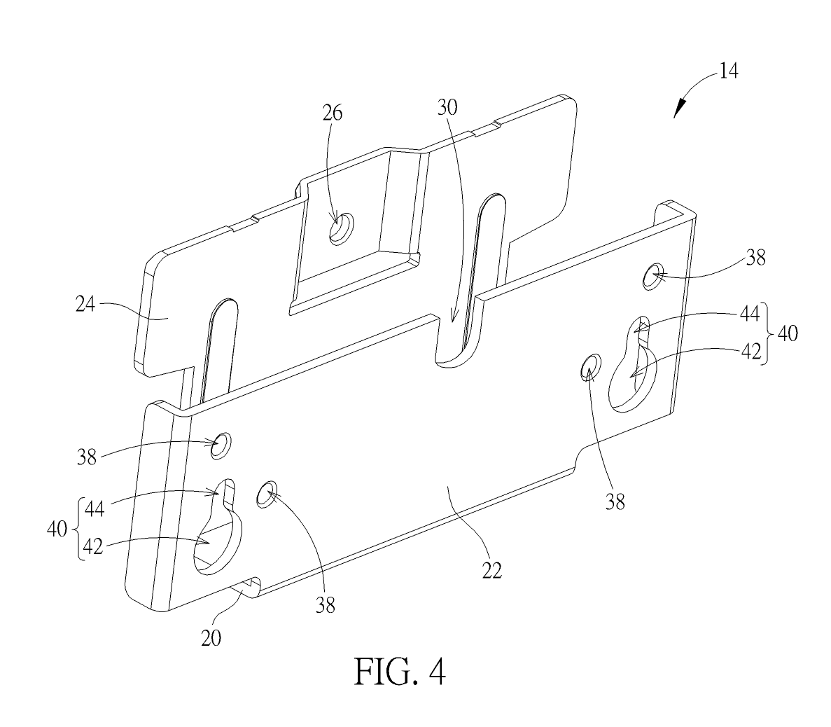

Please refer to FIG. 3 and FIG. 4. FIG. 3 and FIG. 4 respectively are diagrams of the holder 14 in different views according to the embodiment of the present invention. The holder 14 includes a base 20, a positioning portion 22 and an engaging portion 24. The base 20 has a first edge 201 and a second edge 203 opposite to each other. The positioning portion 22 is bent from the first edge 201, the engaging portion 24 is bent from the second edge 203, so that the base 20 is connected between the positioning portion 22 and the engaging portion 24 to form a U-shaped structure. The holder 14 can be hanged on the wall by the positioning portion 22, or be put on the table by the base 20. The engaging portion 24 inserts into the sunken structure 18 of the casing 12 to assemble the holder 14 with the casing 12.

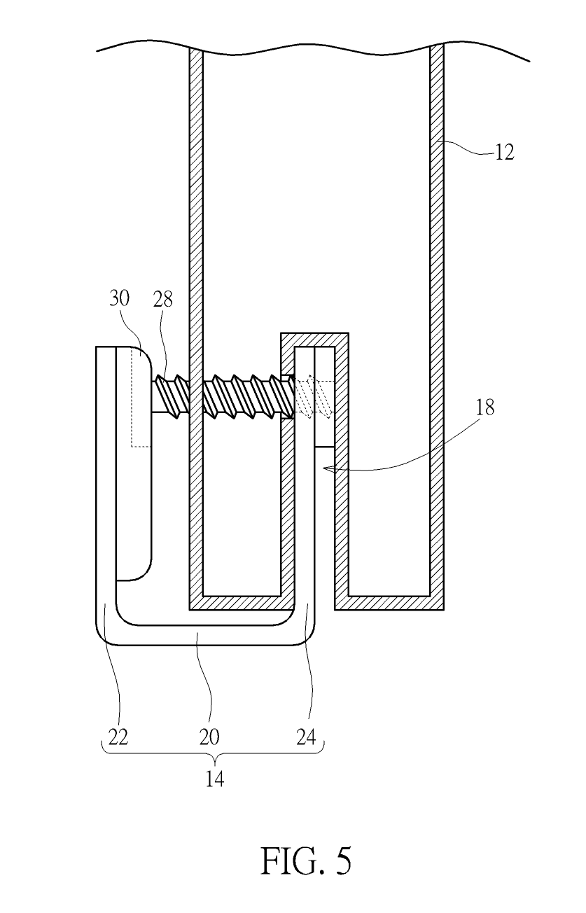

Please refer to FIG. 3 to FIG. 5. FIG. 5 is a sectional view of assembly of the casing 12 and the holder 14 according to a first embodiment of the present invention. In the first embodiment, a piercing hole 26 is formed on the engaging portion 24, and the engaging portion 24 is disposed inside the sunken structure 18. The holder 14 includes a fixing component 28. A thread structure is formed on an outer surface of the fixing component 28, which means the fixing component 28 can be, but not limited to, a screw or a bolt. The fixing component 28 passes through a yielded space 30 of the positioning portion 22 to insert into the casing 12. Then, the fixing component 28 is locked into the casing 12 and simultaneously passes through the piercing hole 26, so as to restrict the engaging portion 24 within the sunken structure 18 and to constrain a relative movement between the holder 14 and the casing 12. The yielded space 30 is an optional design that can be omitted while a distance between the piercing hole 26 and the base 20 is greater than a height of the positioning portion 22, and the fixing component 28 can directly insert into the casing 12 to assemble with the engaging portion 24 inside the sunken structure 18.

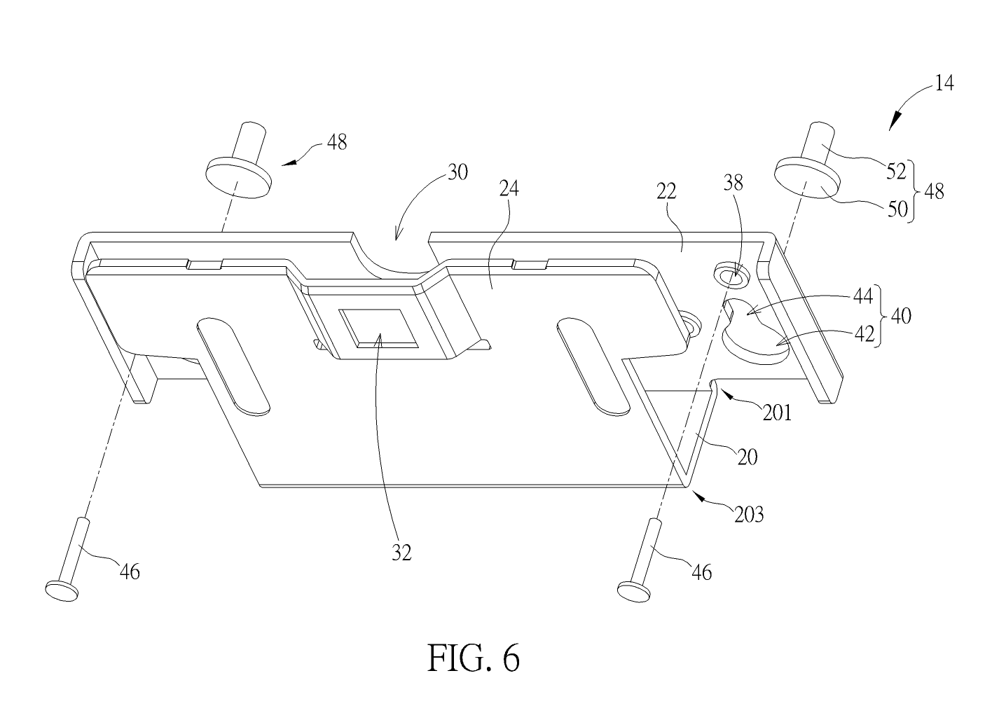

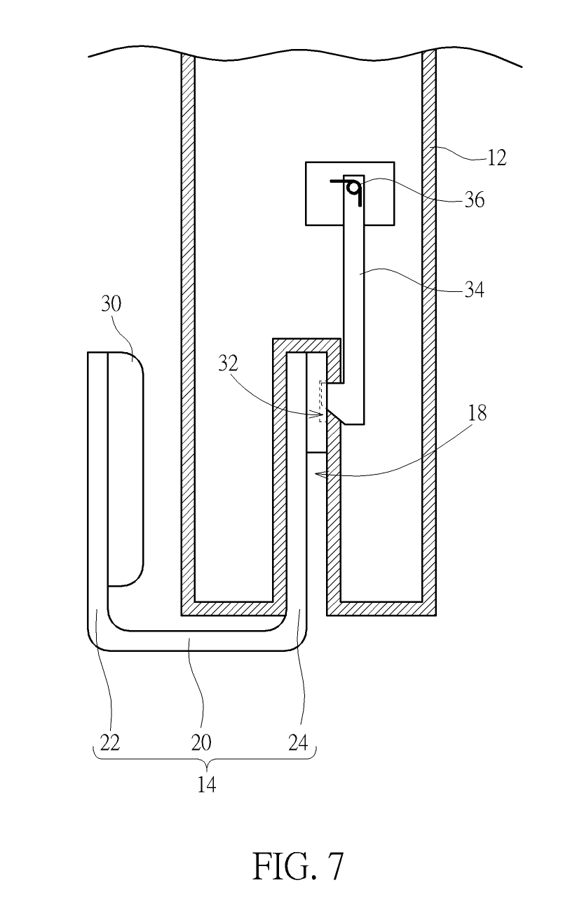

Please refer to FIG. 6 and FIG. 7. FIG. 6 is a diagram of the holder 14 according to a second embodiment of the present invention. FIG. 7 is a sectional view of assembly of the casing 12 and the holder 14 according to the second embodiment of the present invention. In the second embodiment, elements having the same numeral as ones of the first embodiment have the same structures and functions, and a detailed description is omitted herein for simplicity. Difference between the first embodiment and the second embodiment is: the engaging portion 24 of the second embodiment includes a positioning structure 32. The positioning structure 32 can be a rectangular form or a circular form, or further can be a sunken slot that is not penetrated (as the ditch shown in FIG. 6) or a penetrating hole (as the piercing hole 26 shown in FIG. 3), which depends on design demand. The casing 12 further includes a hook 34 disposed inside the casing 12 and adjacent to the sunken structure 18. The hook 34 is engaged inside the positioning structure 32 in a resilient deformable manner to constrain the relative movement between the engaging portion 24 and the sunken structure 18.

The hook 34 can be preferably made of resilient deformable material, so the hook 34 is automatically engaged inside the positioning structure 32 by its own resilient recovering force while the engaging portion 24 inserts into the sunken structure 18. Besides, the hook 34 can be made of inflexible material, and the casing 12 may include a resilient component 36 disposed on the hook 34 accordingly. The resilient component 36 is disposed on a specific position of the hook 34 according to its structural property. For example, the resilient component 36 can be a torsional spring disposed on an end of the hook 34 different from a free end of the hook 34, as shown in FIG. 6. The resilient recovering force of the resilient component 36 presses the hook 34 over the engaging portion 24, and the hook 34 can be tightly engaged inside the positioning structure 32 while the engaging portion 24 completely inserts into the sunken structure 18. The resilient component 36 further can be designed as a compressive spring or an extensible spring disposed on a left side or a right side of the hook 34 (not shown in figures). The hook 34 can be engaged inside the positioning structure 32 by the resilient recovering force of the compressive spring and the extensible spring.

As shown in FIG. 3 and FIG. 4, a locking hole 38 and a hanging hole 40 can be formed on the positioning portion 22. The locking hole 38 is a circular hole or any other form. The hanging hole 40 includes a first part 42 and a second part 44 connected to each other, and dimension of the first part 42 is greater than dimension of the second part 44, so the hanging hole 40 can be viewed as a calabash-shaped form. For stable assembly of the holder 14 on the wall, the thin-typed display 10 utilizes a locking component 46 (such as the screw or the bolt) to pass through the locking hole 38 to lock the positioning portion 22 on the wall. Further, a hanger 48 including a contacting portion 50 and a pin 52 can be installed on the wall. An end of the pin 52 is connected to the contacting portion 50, and dimension of the contacting portion 50 is set between the dimensions of the first part 42 and the second part 44. Since the hanger 48 inserts into the hanging hole 40, the contacting portion 50 firstably passes into the first part 42 and then moves from the first part 42 to the second part 44. The contacting portion 50 is utilized to prevent the hanger 48 from being disassembled from the hanging hole 40 through the second part 44. Amounts and disposition of the locking hole 38 and the hanging hole 40 are not limited to the above-mentioned embodiments, and depend on actual demand. The locking component 46 and the hanger 48 can be utilized simultaneously or alternatively to install the holder 14 on the wall.

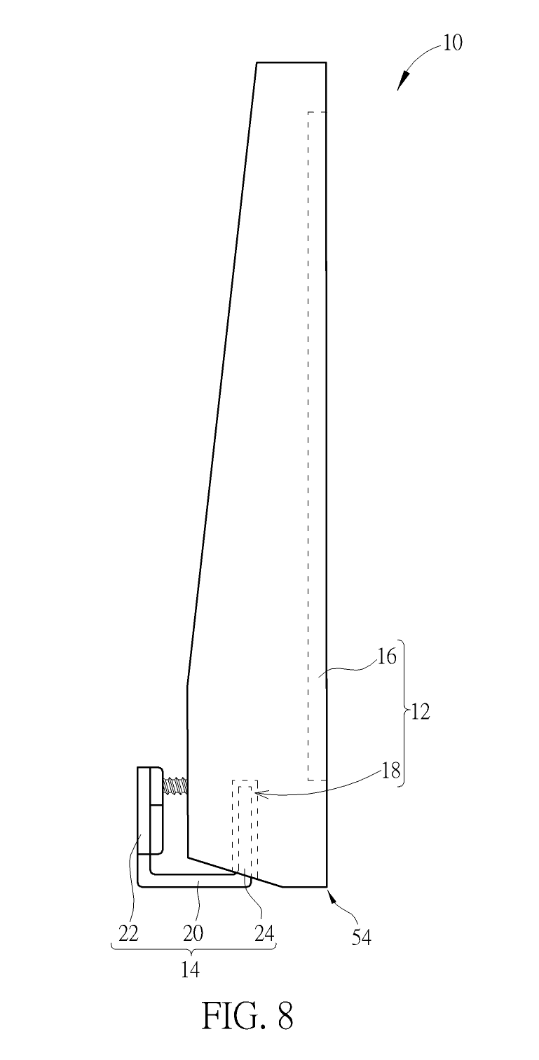

As shown in FIG. 1, the casing 12 further includes a bottom edge 54 located on the lower side of the casing 12. When the engaging portion 24 inserts into the sunken structure 18 to assemble the holder 14 with the casing 12, the base 20 of the holder 14 may protrude from the bottom edge 54 of the casing 12, which means the bottom edge 54 does not align with the base 20, and the thin-typed display 10 can be suspended over a working plane (such as the tabletop) by single support of the base 20. Moreover, please refer to FIG. 8. FIG. 8 is a diagram of the thin-typed display 10 according to another embodiment of the present invention. As shown in FIG. 8, the bottom edge 54 of the casing 12 substantially aligns with the base 20 of the holder 14, which represents the base 20 and the bottom edge 54 are located on the same level, and the thin-typed display 10 can stand upon the working plane by dual support of the bottom edge 54 and the base 20.

In conclusion, the present invention disposes the sunken structure into an interval between components inside the casing instead of increasing thickness of the casing, the holder is detachably assembled with the sunken structure, and the casing can stand upon the table or be hanged on the wall stably by the holder. Comparing to the prior art, the holder is tightly attached to the lower side of the casing, and the thin-typed display of the present invention has advantages of preferred aesthetic appearance and convenient operating process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A thin-typed display capable of being disposed on a wall, the thin-typed display comprising:
a casing whereon a displaying panel is disposed, the casing comprising a sunken structure; and
a holder detachably disposed on the casing, the holder comprising:
a base, having a first edge and a second edge opposite to each other;
a positioning portion bent from the first edge and disposed on the wall; and
an engaging portion bent from the second edge and inserting into the sunken structure to assemble the holder with the casing.

2. The thin-typed display of claim 1, wherein a piercing hole is formed on the engaging portion, the holder further comprises a fixing component, and the fixing component passes through the piercing hole and is locked onto the casing.

3. The thin-typed display of claim 1, wherein the engaging portion comprises a positioning structure, the casing further comprises a hook disposed inside the sunken structure, and the hook is engaged with the positioning structure to constrain a relative movement between the engaging portion and the sunken structure.

4. The thin-typed display of claim 3, wherein the positioning structure is a sunken slot or an opening.

5. The thin-typed display of claim 3, wherein the hook is engaged with the positioning structure in a resilient deformable manner.

6. The thin-typed display of claim 3, wherein the casing further comprises a resilient component disposed on the hook, resilient recovering force of the resilient component drives the hook to engage with the positioning structure.

7. The thin-typed display of claim 1, wherein a locking hole is formed on the positioning portion, a locking component passes through the locking hole to fix the positioning portion onto the wall.

8. The thin-typed display of claim 1, wherein a hanging hole is formed on the positioning portion, a hanger of the wall inserts into the hanging hole to assemble the positioning portion with the wall.

9. The thin-typed display of claim 8, wherein the hanging hole comprises a first part and a second part connected to each other, dimension of a contacting portion of the hanger is set between dimensions of the first part and the second part.

10. The thin-typed display of claim 1, wherein the casing further comprises a bottom edge, when the engaging portion inserts into the sunken structure to assemble the holder with the casing, the base and the bottom edge are located on the same level to stand the thin-typed display upon a working plane by the bottom edge and the base, or the base protrudes out the bottom edge and the thin-typed display is suspended over the working plane by the base.
